(19) United States
(12) Patent Application Publication
(10) Pub. No.: US 2025/0044344 A1
(43) Pub. Date: Feb. 6, 2025

(54) ELECTRICAL CONNECTOR MOUNTED TO BRITTLE SUBSTRATE

(71) Applicant: Tektronix, Inc., Beaverton, OR (US)

(72) Inventors: Forest E. Kernan, Portland, OR (US); Steven Tonthat, Beaverton, OR (US); Matthew D. Borden, Beaverton, OR (US); Kevin Bain Cox, Portland, OR (US); Ghassan Abu-Hamdeh, Beaverton, OR (US); Taylor C. Fling, Forest Grove, OR (US); Stuart Roberts, Beaverton, OR (US)

(21) Appl. No.: 18/783,256

(22) Filed: Jul. 24, 2024

Related U.S. Application Data
(60) Provisional application No. 63/516,636, filed on Jul. 31, 2023.

(51) Int. Cl. G01R 31/28; H01R 12/70; H01R 43/18

(52) U.S. Cl. CPC G01R 31/2818; H01R 12/7011; H01R 43/18

(57) ABSTRACT

A connector assembly that includes an electrical connector having a connector conductor, a connector housing, a PCB substrate bonded to a base, positioning pads extending away from the PCB substrate, and metallic bumps extending away from the PCB substrate. The connector housing has a housing conductor that is electrically connected to the connector conductor. The PCB substrate is brittle, and the housing conductor contacts an electrical signal path on the PCB substrate at an oblique angle. The positioning pads keep the mounting face of the connector housing away from the PCB substrate at a standoff distance. The metallic bumps are malleable and configured to provide an electrical connection between the PCB substrate and the mounting face of the connector housing.

### CROSS-REFERENCE TO RELATED APPLICATIONS

This disclosure is a non-provisional of and claims benefit from U.S. Provisional Application No. 63/516,636, titled “CONNECTOR MOUNT ON GLASS,” filed on Jul. 31, 2023, the disclosure of which is incorporated herein by reference in its entirety.

### TECHNICAL FIELD

This disclosure relates to test and measurement instruments, and more particularly to an electrical connector mounted on a fused silica substrate for a test and measurement instrument for providing a very-low-loss path between a user-facing connector and an ASIC (application-specific integrated circuit) input.

### BACKGROUND

Based on current technology, a DC-110 GHz connector mounted on fused silica quartz would provide the lowest possible loss path between a user-facing connector (i.e. the DC-110 GHz connector) and the input of an ASIC. This is because the highest performance filters (based on current technology) are made on fused silica quartz. This design can facilitate a significant low-noise performance advantage over conventional instruments. In order to move a signal from a DC-110 GHz connector to a fused silica substrate using current technology, however, a transition from a higher loss printed circuit board (PCB) substrate to the fused silica substrate must be made. But these transitions generate reflections in the system and degrade the overall performance of the instrument.

In addition, it can be difficult to mount a connector to a brittle substrate because the substrate is fragile. Previously, no one in industry has successfully demonstrated a productized connector mounted on any hard-material substrates, such as ceramic or glass. Most people attempt to solder or epoxy the connector, but those attachment methods can crack the substrate due to the Coefficient of Thermal Expansion (CTE) mismatch between the materials. Even if the connector is successfully attached without cracking the hard-material substrate, slight mechanical pressure through the body of the connector or short distance drops would crack the substrate.

As a result, current high-frequency connectors are designed to attach to softer PCB materials rather than to brittle substrates. Other interconnections, such as wirebonds or BGA interposers, are then used to get from the soft PCB material to the brittle materials or the ASICS.

Configurations of the disclosed technology address shortcomings in the prior art.

### BRIEF DESCRIPTION OF THE DRAWINGS

FIG. 1 is an isometric view of an example electrical connector mounted to a brittle printed-circuit-board (PCB) substrate, according to an example configuration.

FIG. 2 is a detail view of a portion of FIG. 1, with a portion of the connector housing removed to show internal details.

FIG. 3 is a detail view of a portion of FIG. 2.

FIG. 4 is a plan view of the example PCB substrate of FIG. 1.

FIG. 5 is a sectional view of the example assembly of FIG. 1, taken along the line indicated in FIG. 1.

FIG. 6 is a plan view of another example PCB substrate.

FIG. 7 illustrates an example of method of assembling a connector assembly having a brittle printed-circuit-board (PCB) substrate bonded to a base.

FIG. 8 is a block diagram of an example of a test and measurement instrument system, according to an example configuration.

### DETAILED DESCRIPTION

As described in this document, configurations of the disclosed technology solve the challenge of attaching an electrical connector, such as an RF connector, to a fragile material, such as glass or ceramic PCB, while creating an assembly that is robust enough to use in high performance instruments. Additionally, configurations eliminate the additional transitions that generate reflections as well as the additional loss of the non-glass PCB that would otherwise hold the connector.

Also, configurations of the disclosed technology solve the ruggedness issue so that the brittle substrate will not break when forces are applied to the connector. A significant advantage that the disclosed configurations provide over prior solutions is that the connector is replaceable without scrapping the entire, expensive assembly, including an otherwise functioning module and ASIC. This is because, in such configurations, the connector is not soldered or epoxied in place. Instead, it is removable.

To avoid cracking the substrate during assembly or when forces are applied to the connector, the connector is mounted to a connector housing. The top surface of the substrate is placed such that it is below the surface of the connector housing by a very small amount (such as, for example, 1 mil (25.4 μm)). This standoff is achieved by having the connector housing rest on positioning pads and placing the fused silica with extreme positional accuracy.

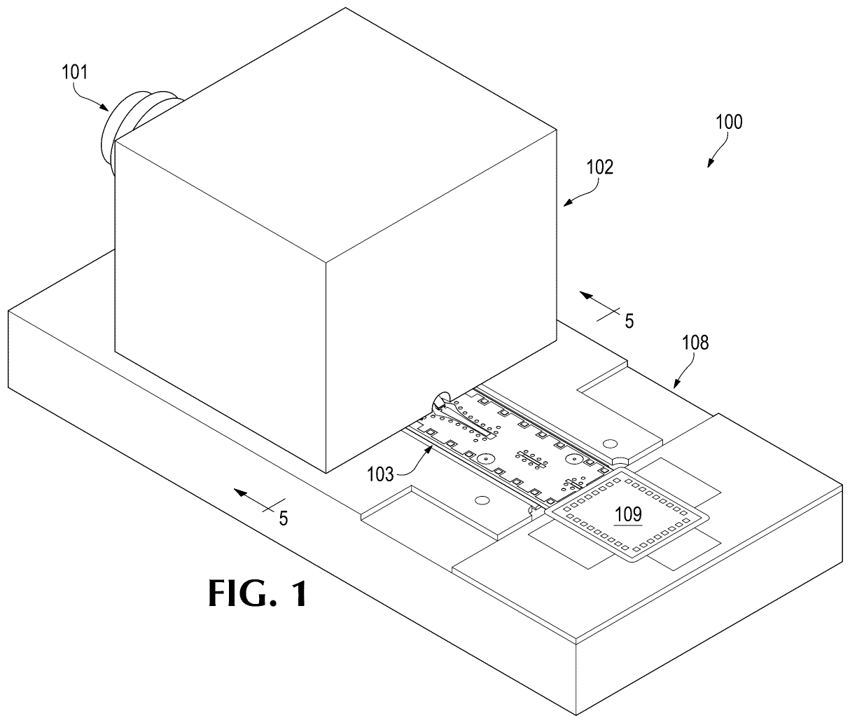

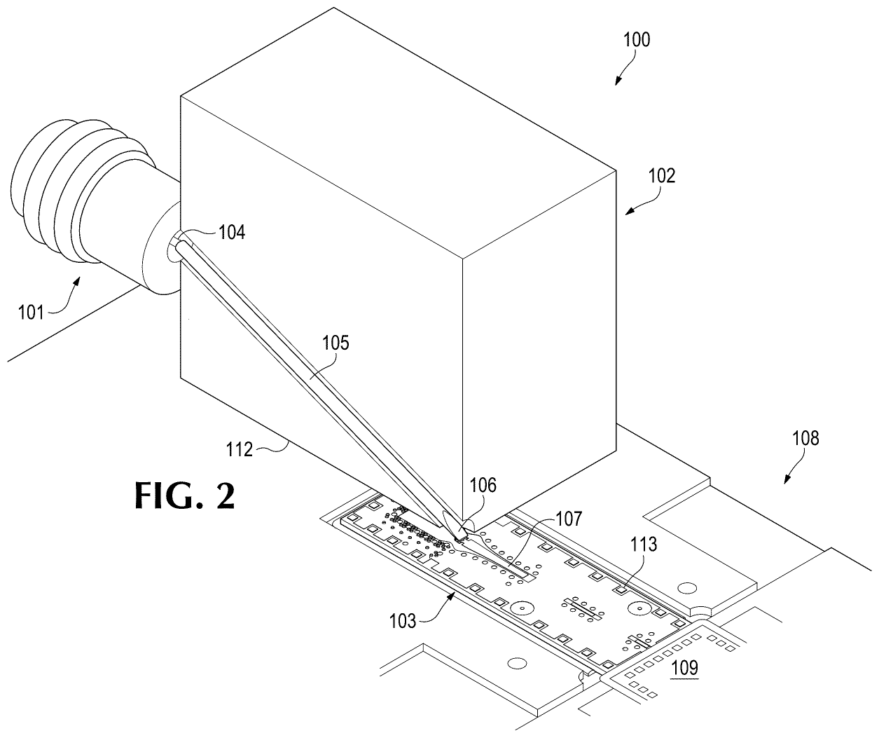

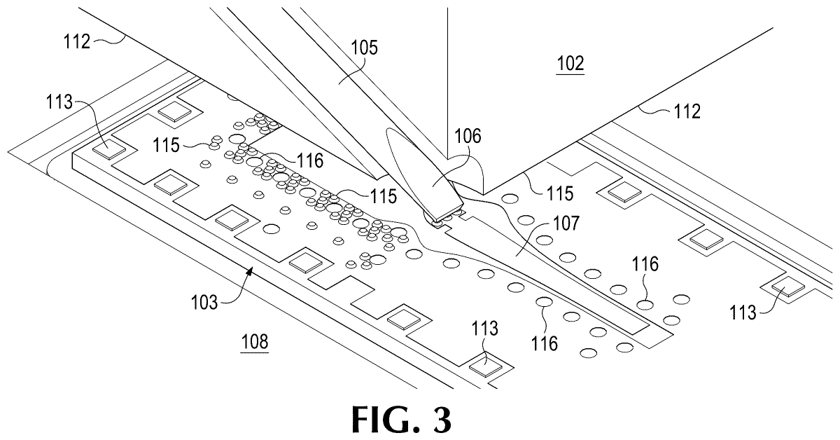

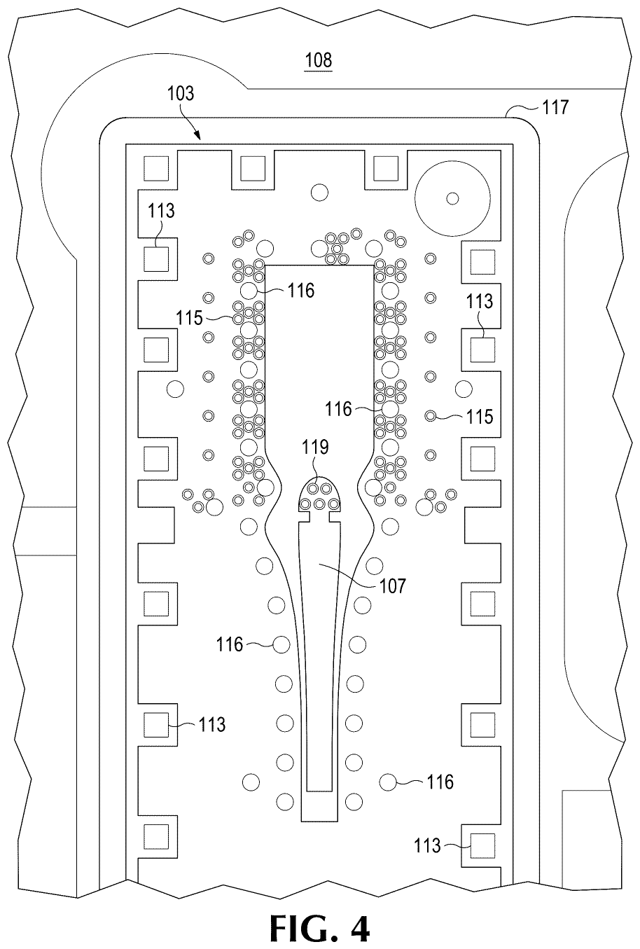

Consequently, FIG. 1 is an isometric view showing portions of an electrical connector 101 mounted to a brittle printed-circuit-board (PCB) substrate, according to an example configuration. FIG. 2 is a detail view of a portion of FIG. 1, with a portion of the connector housing 102 removed to show internal details. FIG. 3 is a detail view of a portion of FIG. 2, and FIG. 4 is a plan view of the example PCB substrate 103 of FIG. 1. As illustrated in FIGS. 1-4, a connector assembly 100 may include an electrical connector 101, a connector housing 102, and a PCB substrate 103.

The electrical connector 101 has a connector conductor 104. In configurations, the electrical connector 101 is a radio-frequency (RF) connector. In configurations, the RF connector is a DC-to-110 GHz connector, meaning the connector has an operational bandwidth of DC to 110 GHz, where DC means direct current or zero Hertz. As noted above, such connectors may be found, for example, as the user-facing connector for a test and measurement instrument, such as an oscilloscope. FIG. 8 shows portions of an example of a test and measurement instrument system in block diagram format. As illustrated in FIG. 8, a test and measurement instrument 120 may include an electrical connector 121 and a signal conditioning circuit 122. The electrical connector 121 is accessible to a user at a housing surface 123 of the test and measurement instrument 120 and is structured to receive a signal from a device under test (DUT) 124. The signal conditioning circuit 122 has an input to receive the signal from the DUT 124. The electrical connector 121 of FIG. 8 may be, for example, the electrical connector 101 discussed in connection FIGS. 1-4. The signal conditioning circuit 122 of FIG. 8 may be, as examples, the ASIC 109 (discussed here in connection FIGS. 1-4) or a field programmable gate array (FPGA).

Returning to FIGS. 1-4, in configurations, the electrical connector 101 is a coaxial connector in which the connector conductor 104 is a center conductor and is surrounded by an outer conductor typically connected to an electrical ground.

The connector housing 102 is substantially rigid. As used in this context, “substantially rigid” means largely or essentially stiff and not pliant, without requiring perfect inflexibility. The connector housing 102 supports the electrical connector 101 and the housing conductor 105 (discussed below). For example, the electrical connector 101 and the housing conductor 105 may each extend from the connector housing 102, which securely holds the electrical connector 101 and the housing conductor 105. Preferably, the housing conductor 105 is not soldered or epoxied in place or otherwise permanently affixed to the PCB substrate 103. Rather, the housing conductor 105 preferably is removable from the PCB substrate 103. In this context, “removable” means that the components can be separated and moved away from each other without causing permanent damage to either component.

In the illustrated configuration, the connector housing 102 has a housing conductor 105 that is electrically connected to the connector conductor 104. For example, as shown in FIG. 2, the housing conductor 105 may be in direct, physical contact with the connector conductor 104. In configurations, the housing conductor 105 may be or include a flat strip, at least at an end 106 of the housing conductor 105 by the PCB substrate 103. In other configurations, the housing conductor 105 may be another shape, such as round. The housing conductor 105 is electrically connected to an electrical signal path 107 on the PCB substrate 103. For example, as best shown in FIG. 3, the housing conductor 105 may be in direct, physical contact with metallic bumps 119 (described below) on the electrical signal path 107 of the PCB substrate 103. Preferably, the housing conductor 105 contacts the PCB substrate 103 at an oblique angle. In other words, the housing conductor 105 is neither parallel nor perpendicular to the PCB substrate 103. This oblique angle helps to keep the load applied to the PCB substrate 103 by the housing conductor 105 lower than if the housing conductor 105 were perpendicular to the PCB substrate 103. It is important to keep the load relatively low to prevent cracking or shattering of a brittle PCB substrate 103. Preferably, the force applied by the housing conductor 105 to the PCB substrate 103 is between about 0.2 N and about 0.8 N. More preferably, the force applied is between about one-third Newton (N) and about two-thirds Newton. Even more preferably, the force applied is between 0.4 N and 0.6 N.

An example of a suitable electrical connector 101 and connector housing 102 is the “PCB launch connector 1.0 mm female DC-110 GHz” provided by Spinner GmbH. Still, applications of the disclosed technology are not limited to this particular connector or to connectors provided by Spinner GmbH.

The PCB substrate 103 is brittle. In other words, the PCB substrate 103 has hardness and rigidity but relatively little tensile strength, so that it breaks easily. In configurations, the PCB substrate 103 is fused silica quartz. In configurations, the PCB substrate 103 is alumina ceramic, which is also sometimes known as alumina or aluminum oxide. In the illustrated configuration, the PCB substrate 103 is bonded to a base 108. In configurations, the base 108 is a metal housing. In configurations, the electrical signal path 107 on the PCB substrate 103 is electrically connected to another circuit, such as an application-specific integrated circuit (ASIC) 109. As an example, the ASIC 109 might control another aspect of a test and measurement instrument. In configurations, the other circuit might be a field programmable gate array (FPGA).

Preferably, the connector housing 102 is not soldered or epoxied in place or otherwise permanently affixed to the base 108. Rather, the connector housing 102 preferably is removable from the base 108, so that the components can be separated and moved away from each other without causing permanent damage to either component. In such configurations, the connector housing 102 can be removed from the base 108 without damaging the base 108 or the PCB substrate 103.

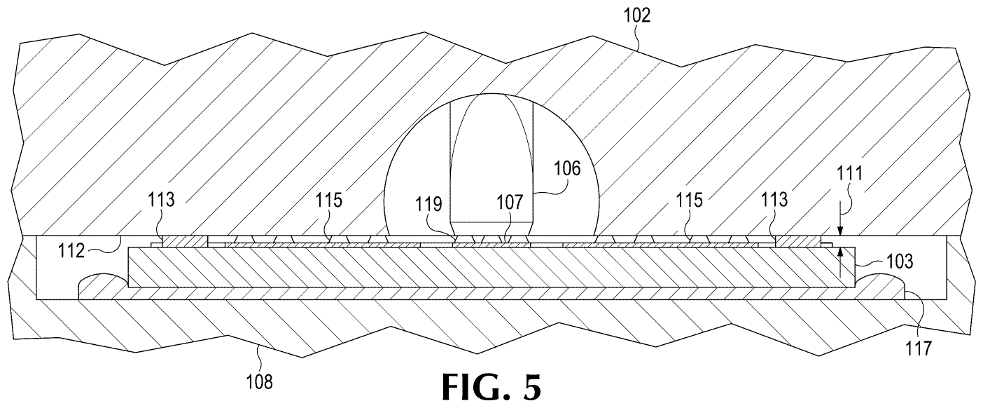

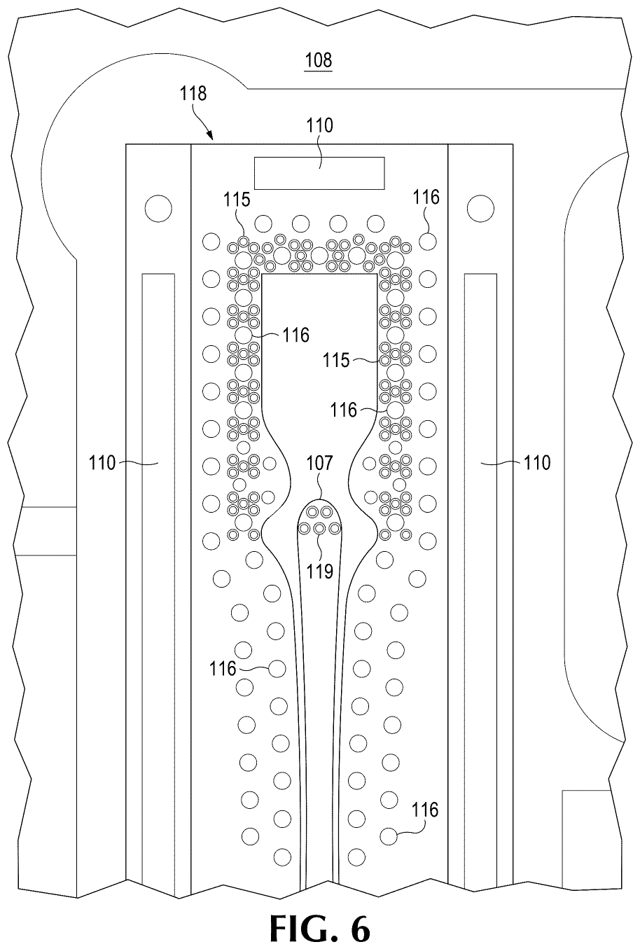

As best illustrated in FIG. 5, positioning pads (illustrated as polyimide pads 113) extend away from the PCB substrate 103 to a standoff distance 111. In other words, the height of the positioning pads is the standoff distance 111. In configurations, the positioning pads are polymer pads, such as the polyimide pads 113 illustrated in FIGS. 1-5. In configurations, the positioning pads are solder mask dams 110, such as illustrated in FIG. 6. The positioning pads contact a mounting face 112 of the connector housing 102 and keep the mounting face 112 of the connector housing 102 away from the PCB substrate 103 at the standoff distance 111. As a result, the connector housing 102 does not touch the PCB substrate 103. Preferably, the standoff distance 111 is between about 0.3 mil and about 1.7 mil. More preferably, the standoff distance 111 is between about 0.6 mil and about 1.3 mil. Even more preferably, the standoff distance 111 is between 0.9 mil and 1.1 mil. One mil is 25.4 micrometers (μm).

As illustrated, metallic bumps 115, 119 extend away from the PCB substrate 103 and contact the mounting face 112 of the connector housing 102 when the connector housing 102 is installed. In configurations where the electrical connector 101 is a coaxial connector, the metallic bumps 119 connect the center conductor of the coax connector, through the housing conductor 105, to the signal path 107, while the main body of the connector housing 102 connects the outer conductor of the coax connector to the metallic bumps 115, for example through mounting face 112, as a ground path. Accordingly, the metallic bumps 115 provide an electrical connection between the PCB substrate 103 and the mounting face 112 of the connector housing 102. The metallic bumps 119 provide an electrical connection between the PCB substrate 103 and the housing conductor 104. The metallic bumps 115, 119 are malleable. Accordingly, before assembly, the metallic bumps 115, 119 may be taller (i.e. extend away from the PCB substrate 103 more) than the standoff distance 111. Because they are malleable, the metallic bumps 115, 119 may be compressed when the connector housing 102 is positioned on the base 108 to help ensure that the metallic bumps 115, 119 make the connection between the PCB substrate 103 and the mounting face 112 of the connector housing 102 or between the PCB substrate 103 and the housing conductor 104. In configurations, the metallic bumps 115, 119 are gold bumps. As best illustrated in FIGS. 4 and 6, the metallic bumps 115 may be grouped around vias 116 on the PCB substrate 103.

FIG. 5 is a sectional view of the example assembly of FIG. 1, taken along the line indicated in FIG. 1. As illustrated in FIG. 5, the connector housing 102 is resting on the positioning pads (illustrated as polyimide pads 113) at the standoff distance 111 from the PCB substrate 103. The metallic bumps 115, 119 bridge the gap between the connector housing 102 and the PCB substrate 103 or between the PCB substrate 103 and the housing conductor 104. The housing conductor 105 is contacting the PCB substrate 103 at an oblique angle.

FIG. 6 is a plan view of another example PCB substrate 118 that would be suitable as a substitute for the PCB substrate 103 discussed above for FIGS. 1-5. Items labeled in FIG. 6 are as described above for FIGS. 1-5 except as noted here. The principal differences between the configuration in FIG. 6 and the configuration in FIGS. 1-5 are in the positioning pads and in the artwork for the PCB substrate 118. Specifically, as noted above, the positioning pads of FIG. 6 are solder mask dams 110, whereas the positioning pads of FIGS. 1-5 are polyimide pads 113.

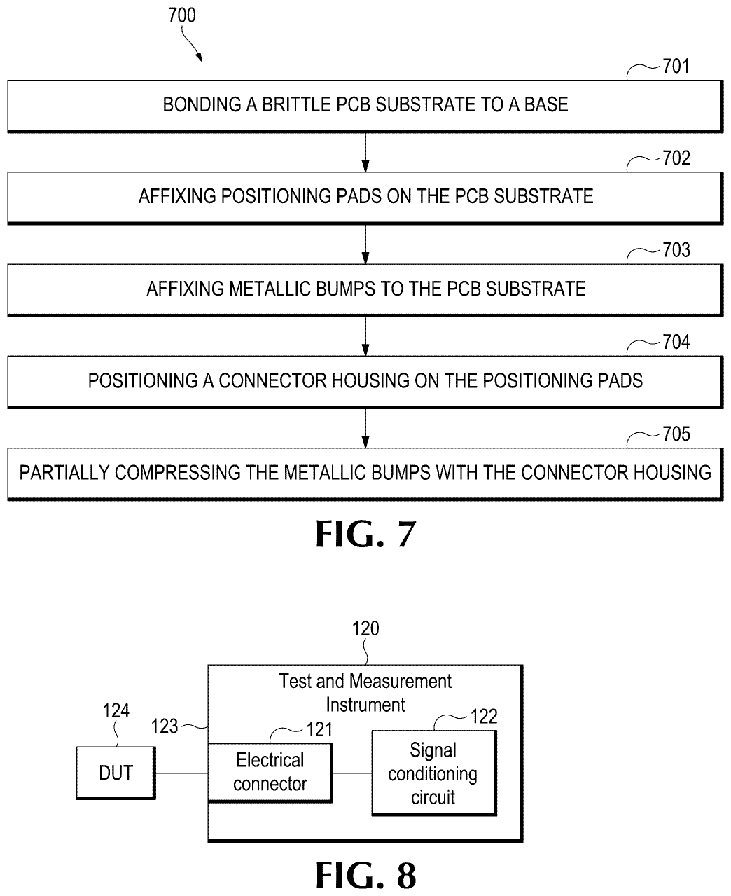

Accordingly, and with reference to FIG. 7, a method 700 of assembling a connector assembly 100 may include bonding 701 a brittle printed-circuit-board (PCB) substrate to a base 108; affixing 702 positioning pads on at least two sides of the PCB substrate 103, the positioning pads extending away from the PCB substrate 103 to a standoff distance 111; affixing 703 metallic bumps 115, 119 to the PCB substrate 103, the metallic bumps 115, 119 extending away from the PCB substrate 103 a distance greater than the standoff distance 111; positioning 704 a connector housing 102 on the positioning pads, the connector housing 102 being substantially rigid and supporting an electrical connector 101, the connector housing 102 having a housing conductor 105 that is electrically connected to a connector conductor 104 of the electrical connector 101; and partially compressing 705 the metallic bumps 115, 119 with the connector housing 102, the metallic bumps 115, 119 providing an electrical connection between the PCB substrate 103 and a mounting face 112 of the connector housing 102 or between the PCB substrate 103 and the housing conductor 104.

In a variation of the method 700, bonding the PCB substrate 103 to the base 108 includes applying a soft epoxy 117 between the PCB substrate 103 and the base 108, pressing the PCB substrate 103 into the base 108, squeezing out excess soft epoxy 117 from between the PCB substrate 103 and the base 108, and curing the soft epoxy 117 to bond the PCB substrate 103 to the base 108.

In a variation of the method 700, positioning the connector housing 102 on the positioning pads includes positioning the connector housing 102 on the positioning pads using a thermocompression bonder, such as a thermocompression bonder provided by Finetech.

### EXAMPLES

Illustrative examples of the disclosed technologies are provided below. A particular configuration of the technologies may include one or more, and any combination of, the examples described below.

Example 1 includes a connector assembly comprising: an electrical connector having a connector conductor; a connector housing, the connector housing being substantially rigid and supporting the electrical connector, the connector housing having a housing conductor that is electrically connected to the connector conductor; a printed-circuit-board (PCB) substrate bonded to a base, the PCB substrate being brittle, the housing conductor contacting an electrical signal path on the PCB substrate at an oblique angle; positioning pads extending away from the PCB substrate to a standoff distance, the positioning pads contacting a mounting face of the connector housing and keeping the mounting face of the connector housing away from the PCB substrate at the standoff distance; and metallic bumps extending away from the PCB substrate, the metallic bumps contacting the mounting face of the connector housing, the metallic bumps being malleable and configured to provide an electrical connection between the PCB substrate and the mounting face of the connector housing.

Example 2 includes the connector assembly of Example 1, in which the electrical connector is a radio-frequency (RF) connector.

Example 3 includes the connector assembly of Example 2, in which the RF connector is a direct current (DC)-to-110 GHz connector.

Example 4 includes the connector assembly of any of Examples 1-3, in which the electrical signal path of the PCB substrate electrically connects the housing conductor to an application-specific integrated circuit.

Example 5 includes the connector assembly of any of Examples 1-3, in which the PCB substrate is fused silica quartz.

Example 6 includes the connector assembly of any of Examples 1-3, in which the PCB substrate is alumina ceramic.

Example 7 includes the connector assembly of any of Examples 1-6, in which the positioning pads are polymer pads.

Example 8 includes the connector assembly of Example 7, in which the polymer pads are polyimide pads.

Example 9 includes the connector assembly of any of Examples 1-6, in which the positioning pads are solder mask dams.

Example 10 includes the connector assembly of any of Examples 1-9, in which the base is a metal housing.

Example 11 includes the connector assembly of any of Examples 1-10, in which the metallic bumps are gold bumps.

Example 12 includes the connector assembly of any of Examples 1-11, in which the housing conductor comprises a flat strip at an end of the housing conductor that contacts the electrical signal path on the PCB substrate.

Example 13 includes the connector assembly of any of Examples 1-12, further comprising additional metallic bumps extending away from the electrical signal path on the PCB substrate, the additional metallic bumps contacting the housing conductor of the connector housing, the additional metallic bumps being malleable and configured to provide an electrical connection between the electrical signal path on the PCB substrate and the housing conductor.

Example 14 includes a method of assembling a connector assembly comprising: bonding a brittle printed-circuit-board (PCB) substrate to a base; affixing positioning pads on at least two sides of the PCB substrate, the positioning pads extending away from the PCB substrate to a standoff distance; affixing metallic bumps to the PCB substrate, the metallic bumps extending away from the PCB substrate a distance greater than the standoff distance; positioning a connector housing on the positioning pads, the connector housing being substantially rigid and supporting an electrical connector, the connector housing having a housing conductor that is electrically connected to a connector conductor of the electrical connector; and partially compressing the metallic bumps with the connector housing, the metallic bumps providing an electrical connection between the PCB substrate and a mounting face of the connector housing.

Example 15 includes the method of Example 14, in which bonding the PCB substrate to the base includes applying a soft epoxy between the PCB substrate and the base, pressing the PCB substrate into the base, squeezing out excess soft epoxy from between the PCB substrate and the base, and curing the soft epoxy to bond the PCB substrate to the base.

Example 16 includes the method of any of Examples 14-15, in which positioning the connector housing on the positioning pads includes positioning the connector housing on the positioning pads using a thermocompression bonder.

Example 17 includes a test and measurement instrument, comprising: an electrical connector accessible to a user at a housing surface of the test and measurement instrument and structured to receive a signal from a device under test (DUT), the electrical connector having a connector conductor; a signal conditioning circuit having an input to receive the signal from the DUT; a connector housing, the connector housing being substantially rigid and supporting the electrical connector, the connector housing having a housing conductor that is electrically connected to the connector conductor; a printed-circuit-board (PCB) substrate bonded to a base, the PCB substrate being brittle, the housing conductor contacting an electrical signal path on the PCB substrate at an oblique angle, in which the electrical signal path of the PCB substrate electrically connects the housing conductor to the input of the signal conditioning circuit; positioning pads extending away from the PCB substrate to a standoff distance, the positioning pads contacting a mounting face of the connector housing and keeping the mounting face of the connector housing away from the PCB substrate at the standoff distance; and metallic bumps extending away from the PCB substrate, the metallic bumps contacting the mounting face of the connector housing, the metallic bumps being malleable and configured to provide an electrical connection between the PCB substrate and the mounting face of the connector housing.

Example 18 includes the test and measurement instrument of Example 17, in which the signal conditioning circuit comprises an application-specific integrated circuit (ASIC).

Example 19 includes the test and measurement instrument of Example 18, in which the ASIC is mounted on the PCB substrate.

Example 20 includes the test and measurement instrument of Example 17, in which the signal conditioning circuit comprises a field programmable gate array (FPGA).

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

Additionally, this written description makes reference to particular features. It is to be understood that the disclosure in this specification includes all possible combinations of those particular features. For example, where a particular feature is disclosed in the context of a particular aspect, that feature can also be used, to the extent possible, in the context of other aspects.

Also, when reference is made in this application to a method having two or more defined steps or operations, the defined steps or operations can be carried out in any order or simultaneously, unless the context excludes those possibilities.

Although specific aspects of the disclosure have been illustrated and described for purposes of illustration, it will be understood that various modifications may be made without departing from the spirit and scope of the disclosure.

We claim:

1. A connector assembly comprising:
an electrical connector having a connector conductor;
a connector housing, the connector housing being substantially rigid and supporting the electrical connector, the connector housing having a housing conductor that is electrically connected to the connector conductor;
a printed-circuit-board (PCB) substrate bonded to a base, the PCB substrate being brittle, the housing conductor contacting an electrical signal path on the PCB substrate at an oblique angle;
positioning pads extending away from the PCB substrate to a standoff distance, the positioning pads contacting a mounting face of the connector housing and keeping the mounting face of the connector housing away from the PCB substrate at the standoff distance; and
metallic bumps extending away from the PCB substrate, the metallic bumps contacting the mounting face of the connector housing, the metallic bumps being malleable and configured to provide an electrical connection between the PCB substrate and the mounting face of the connector housing.

2. The connector assembly of claim 1, in which the electrical connector is a radio-frequency (RF) connector.

3. The connector assembly of claim 2, in which the RF connector is a direct current (DC)-to-110 GHz connector.

4. The connector assembly of claim 1, in which the electrical signal path of the PCB substrate electrically connects the housing conductor to an application-specific integrated circuit.

5. The connector assembly of claim 1, in which the PCB substrate is fused silica quartz.

6. The connector assembly of claim 1, in which the PCB substrate is alumina ceramic.

7. The connector assembly of claim 1, in which the positioning pads are polymer pads.

8. The connector assembly of claim 7, in which the polymer pads are polyimide pads.

9. The connector assembly of claim 1, in which the positioning pads are solder mask dams.

10. The connector assembly of claim 1, in which the base is a metal housing.

11. The connector assembly of claim 1, in which the metallic bumps are gold bumps.

12. The connector assembly of claim 1, in which the housing conductor comprises a flat strip at an end of the housing conductor that contacts the electrical signal path on the PCB substrate.

13. The connector assembly of claim 1, further comprising additional metallic bumps extending away from the electrical signal path on the PCB substrate, the additional metallic bumps contacting the housing conductor of the connector housing, the additional metallic bumps being malleable and configured to provide an electrical connection between the electrical signal path on the PCB substrate and the housing conductor.

14. A method of assembling a connector assembly comprising:
bonding a brittle printed-circuit-board (PCB) substrate to a base;
affixing positioning pads on at least two sides of the PCB substrate, the positioning pads extending away from the PCB substrate to a standoff distance;
affixing metallic bumps to the PCB substrate, the metallic bumps extending away from the PCB substrate a distance greater than the standoff distance;
positioning a connector housing on the positioning pads, the connector housing being substantially rigid and supporting an electrical connector, the connector housing having a housing conductor that is electrically connected to a connector conductor of the electrical connector; and
partially compressing the metallic bumps with the connector housing, the metallic bumps providing an electrical connection between the PCB substrate and a mounting face of the connector housing.

15. The method of claim 14, in which bonding the PCB substrate to the base includes applying a soft epoxy between the PCB substrate and the base, pressing the PCB substrate into the base, squeezing out excess soft epoxy from between the PCB substrate and the base, and curing the soft epoxy to bond the PCB substrate to the base.

16. The method of claim 14, in which positioning the connector housing on the positioning pads includes positioning the connector housing on the positioning pads using a thermocompression bonder.

17. A test and measurement instrument, comprising:
an electrical connector accessible to a user at a housing surface of the test and measurement instrument and structured to receive a signal from a device under test (DUT), the electrical connector having a connector conductor;
a signal conditioning circuit having an input to receive the signal from the DUT;
a connector housing, the connector housing being substantially rigid and supporting the electrical connector, the connector housing having a housing conductor that is electrically connected to the connector conductor;
a printed-circuit-board (PCB) substrate bonded to a base, the PCB substrate being brittle, the housing conductor contacting an electrical signal path on the PCB substrate at an oblique angle, in which the electrical signal path of the PCB substrate electrically connects the housing conductor to the input of the signal conditioning circuit;
positioning pads extending away from the PCB substrate to a standoff distance, the positioning pads contacting a mounting face of the connector housing and keeping the mounting face of the connector housing away from the PCB substrate at the standoff distance; and
metallic bumps extending away from the PCB substrate, the metallic bumps contacting the mounting face of the connector housing, the metallic bumps being malleable and configured to provide an electrical connection between the PCB substrate and the mounting face of the connector housing.

18. The test and measurement instrument of claim 17, in which the signal conditioning circuit comprises an application-specific integrated circuit (ASIC).

19. The test and measurement instrument of claim 18, in which the ASIC is mounted on the PCB substrate.

20. The test and measurement instrument of claim 17, in which the signal conditioning circuit comprises a field programmable gate array (FPGA).
